(19) United States
(12) Patent Application Publication
(10) Pub. No.: US 2005/0132952 A1
(43) Pub. Date: Jun. 23, 2005

(54) Semiconductor alloy with low surface roughness, and method of making the same

(76) Inventors: Michael Ward, Phoenix, AZ (US); Douglas Webb, Phoenix, AZ (US); James Sellar, Scottsdale, AZ (US); Jeffrey Robinson, Gilbert, AZ (US)

Correspondence Address: ATMI, INC., 7 COMMERCE DRIVE, DANBURY, CT, 06810, US

(21) Appl. No.: 10/738,353

(22) Filed: Dec. 17, 2003

(51) Int. Cl. B32B 15/00; B32B 9/00; C30B 23/00; C30B 25/00; C30B 28/12; C30B 28/14

(52) U.S. Cl. 117/89

(57) ABSTRACT

A compositionally-graded, strain relaxed Si₁₋ₓGeₓ (0<x<1) material having a surface roughness of less than 1 nm. In a preferred aspect, the compositionally-graded material is Si₁₋ₓGeₓ (0<x<0.3) material having a threading dislocation density <1×10⁵ defects/cm² of surface area. The compositionally-graded material is readily formed by vapor deposition or other suitable technique, in which the temperature is selectively modulated during the growth process, optionally with modulation of germanium precursor flow rate, to produce a low surface roughness, low threading dislocation defect density graded silicon-germanium film suitable for forming strained heterostructures such as Si₁₋ₓGeₓ/Si.

### BACKGROUND OF THE INVENTION

1. Field of the Invention

This invention relates to low surface roughness semiconductor alloys, more specifically to a compositionally-graded, strain-relaxed Si₁₋ₓGeₓ material having low surface roughness, to heterostructures including such compositionally-graded material, e.g., Si₁₋ₓGeₓ/Si material having low surface roughness, and to a process for producing such low surface roughness material and heterostructures including same.

2. Description of the Prior Art

In the production of epitaxial layers for fabrication of microelectronic devices, it has been demonstrated that forming epitaxial silicon layers under tensile strain can improve device performance. For example, Currie et al. in J. Vac. Sci. Technol. B 19(6), November/December 2001 describe performance enhancements of strained silicon devices over bulk silicon devices.

One technique for forming silicon under tensile strain involves depositing silicon onto a strain-relaxed Si₁₋ₓGeₓ layer. Such strain-relaxed Si₁₋ₓGeₓ layer is sometimes referred to as a virtual substrate. Deposition of strained silicon layers onto virtual substrates has been an active area of research for a number of years (Fitzgerald et al, Appl. Phys. Lett., 59, (1991) 811). The challenge in such virtual substrate processes is depositing a fully-relaxed, low defect, smooth Si₁₋ₓGeₓ layer to serve as an optimum substrate for the strained silicon deposition step and the subsequent device structure. Defects present in the virtual substrate (Larsen, Mat. Sci. and Eng. B71, (2000) 6-13) can propagate into the strained silicon layer and degrade device performance. A primary goal of the device builder using strain relaxed Si₁₋ₓGeₓ is to reduce the number of defects in the Si₁₋ₓGeₓ layer that can affect the strained Si layer.

A common approach to depositing strain-relaxed Si₁₋ₓGeₓ layers is compositionally grading the Si₁₋ₓGeₓ layer, so that it compositionally ranges over its thickness from pure silicon at one face of the material to the desired germanium concentration at the other face. Brasen et al. U.S. Pat. No. 5,221,413 discloses a method of forming compositionally-graded Si₁₋ₓGeₓ layers at temperatures in excess of 850° C. Legoues et al. U.S. Pat. No. 5,810,924 also describes a process of forming compositionally-graded Si₁₋ₓGeₓ layers. In the approach described in these references, a reduction of misfit and threading dislocations is attributed to the compositional grading process. Compositional grading reduces the driving force for misfit dislocation and associated threading dislocation formation through a continuum of low mismatch interfaces in the graded region. Threading dislocations, which intersect the surface of the film, have the potential to move across a wafer and be annihilated at the edge of the wafer during this process.

Compositional grading of Si₁₋ₓGeₓ has resulted in threading dislocation density levels as low as 10⁵/cm², as reported by Leitz et al, J. Appl. Phys., Vol. 90, No. 6, 15 Sep. 2001. Misfit dislocations, however, typically remain at the interface where they have formed, each creating a small displacement in the vertical direction in the crystal lattice. The vertical displacements can combine to create larger vertical displacements and localized strain in the film, with a resulting three-dimensional roughening of the surface commonly referred to as cross-hatch. Severe cross-hatch will render the surface of the film unsuitable for device formation, since subsequent strained silicon layers deposited on the excessively roughened Si₁₋ₓGeₓ surface will have degraded device performance.

While the cross-hatch surface roughness in compositionally-graded Si₁₋ₓGeₓ layers has been correlated with the occurrence of misfit dislocations, the exact mechanism affecting the degree of the cross-hatch phenomenon has been the subject of continuing study. Hsu et al. (Appl. Phys. Lett., 61, (1992) 1293) has reported that strain fields associated with the misfit dislocation influence the local growth rate, increasing the roughness of the cross-hatch. This finding has been confirmed by Yu et al. (Appl. Phys. Lett., Vol.64, No. 24, 13 Jun. 1994, 3305). Li et al. (J. Vac. Sci. Technol. B 16(3), May/June 1998), however, reported that surface roughness is a primarily a result of a summation of misfit slip steps due to the dislocations, while acknowledging that three-dimensional growth may be affected by periodic variations in the surface.

Process conditions that have been reported to modify the degree of cross-hatch have primarily involved the grading rate of the Si₁₋ₓGeₓ layer and deposition temperature. For a Si₁₋ₓGeₓ, x=0.2 final concentration, the aforementioned Li et al. reference reported that low grading rates of 5% Ge/μm were necessary to achieve a surface roughness of 1.4 nm. Pidduck et al. (Proceedings Microsc. Semicond. Mater. Conf., Oxford, 7-10 Apr. 1997) reported a surface roughness of 2-6 nm for Si₁₋ₓGeₓ, x=0.23 at a grading rate of 5% Ge/μm. Pidduck also reported that higher temperatures, of ≧800° C., are necessary. Kazuki et al. (Mat. Res. Soc. Symp. Proc. Vol. 648, 2001) reported surface roughness results for Si₁₋ₓGeₓ, x=0.3 for three grading schemes (linear grading, step and step-graded) at temperatures of 650-800° C. at 5-30% Ge/μm, in which the best roughness values were 1.2 nm at 5% Ge/μm.

The foregoing studies reflect the fact that the best surface roughness heretofore achieved by the art in fully-relaxed, compositionally-graded Si₁₋ₓGeₓ, x≦0.3 layers is in excess of 1.0 nm.

The efforts to minimize surface roughness is complicated by the fact that such efforts have concurrently produced undesirably high levels of threading dislocation density. For example, in reducing the surface roughness from 3 nm to 1.2 nm through appropriate selection of growth conditions, threading dislocation density may increase from 4×10⁴/cm² to 4×10⁵/cm².

To date, no process has been reported that enables surface roughness ≦1.0 nm to be obtained in a fully-relaxed, compositionally-graded Si₁₋ₓGeₓ, x≦0.3 material, while achieving a threading dislocation density <1×10⁵ threading dislocation defects/cm² of surface area.

### SUMMARY OF THE INVENTION

The present invention relates to low surface roughness semiconductor alloys, more specifically to a compositionally-graded, strain-relaxed Si₁₋ₓGeₓ material having low surface roughness, wherein 0<x<1, as well as to heterostructures including such compositionally-graded material, e.g., Si₁₋ₓGeₓ/Si material having low surface roughness, and to a process for producing such low surface roughness material, and heterostructures including same.

In one aspect, the invention relates to a compositionally-graded, strain-relaxed Si₁₋ₓGeₓ material having a surface roughness of less than 1 nm, wherein 0<x<1.

In another embodiment, the invention relates to a compositionally-graded, strain-relaxed Si₁₋ₓGeₓ (x≦0.3) material with surface roughness less than 1 nm, and threading dislocation density <1×10⁵ threading dislocation defects/cm² of surface area.

A further aspect of the invention relates to an epitaxial heterostructure, comprising a compositionally-graded, strain-relaxed Si₁₋ₓGeₓ epitaxial layer having a surface roughness of less than 1 nm, wherein 0<x<1, and a heterostructural material deposited on the compositionally-graded, strain-relaxed Si₁₋ₓGeₓ epitaxial layer.

A still further aspect of the invention relates to a compositionally-graded, strain-relaxed Si₁₋ₓGeₓ epitaxial layer on a substrate formed by a process comprising contacting silicon and germanium precursor gases with the substrate under vapor deposition conditions comprising controlled temperature ramping, wherein the compositionally-graded, strain-relaxed Si₁₋ₓGeₓ epitaxial layer has a surface roughness of less than 1 nm and a threading dislocation density less than 1×10⁵ threading dislocation defects/cm² of surface area.

In another aspect, the invention relates to a method of forming on a substrate a compositionally-graded, strain-relaxed Si₁₋ₓGeₓ (0<x<1) epitaxial layer having a surface roughness of less than 1 nm, the method including contacting silicon and germanium precursors with the substrate under Si₁₋ₓGeₓ (0<x<1) epitaxial layer growth conditions, and varying temperature, e.g., by ramping of temperature, during at least part of such contacting.

As used in such context, the term “ramping” in reference to temperature means that the temperature in the silicon and germanium precursors contacting step is continuously varied, e.g., in a linear or non-linear fashion, during at least part of the contacting step.

As used herein, the term “surface roughness” means average surface roughness as measured by atomic force microscope (AFM) on a 10 μm×10 μm area of the surface of the graded Si₁₋ₓGeₓ (0<x<1) material.

Other aspects, features and embodiments of the invention will be more fully apparent from the ensuing disclosure and appended claims.

### BRIEF DESCRIPTION OF THE DRAWINGS

FIG. 1 is a graph of germanium concentration in atomic percent as a function of thickness in a graded 2 μm thick Si₁₋ₓGeₓ layer (line A), with lines B and C showing deposition temperature, in ° C., as a function of layer thickness during the deposition process.

FIG. 2 is a graph of deposition temperature, in ° C., as a function of germanium concentration, in atomic percent, of a Si₁₋ₓGeₓ layer formed in accordance with the present invention.

FIG. 3 is an Arrhenius plot of Si₁₋ₓGeₓ deposition rate, in Å/minute, as a function of the inverse deposition temperature, in units of 10³ ° K⁻¹, for a Si₁₋ₓGeₓ layer formed in accordance with the present invention.

### DETAILED DESCRIPTION OF THE INVENTION, AND PREFERRED EMBODIMENTS THEREOF

The present invention relates to a compositionally-graded, strain-relaxed Si₁₋ₓGeₓ/Si material having average surface roughness of less than 1 nanometer (nm), and to a process for producing such low surface roughness material.

The compositionally-graded Si₁₋ₓGeₓ layer of the invention provides a suitable base for growth of strained silicon or heterostructure materials such as SiGe, Si, Ge, GaAs, etc., at average surface roughness below 1 nm.

While the compositionally-graded Si₁₋ₓGeₓ layer of the invention can be formed in any suitable manner, a preferred approach utilizes a chemical vapor deposition operation (e.g. reduced pressure chemical vapor deposition, high vacuum chemical vapor deposition, atmospheric pressure chemical vapor deposition or the like) for contacting silicon and germanium precursor gases with the substrate to form the compositionally-graded Si₁₋ₓGeₓ layer. The Si₁₋ₓGeₓ layer is grown with a gradual increase in Ge-content from pure silicon at the interface with the silicon substrate, to some ultimate composition (Ge concentration) at the top surface of the Si₁₋ₓGeₓ layer. A final capping layer may then be grown at the ultimate composition, followed by strained silicon or some combination of heterostructure material.

We have discovered that during the chemical vapor deposition of a compositionally-graded Si₁₋ₓGeₓ layer, the amount of surface roughness varies with the growth temperature, and therefore that temperature can be modulated during the growth process to produce a compositionally-graded Si₁₋ₓGeₓ layer having extremely low roughness, below levels that have heretofore been obtainable in the art. The surface roughness of compositionally-graded Si₁₋ₓGeₓ films in the practice of the present invention is <1 nm, and more preferably ≦0.9.

The effect of growth temperature on the surface roughness of the compositionally-graded Si₁₋ₓGeₓ layer is shown by the data in Table 1 below. This table sets out the average surface roughness, in nm, for a 10 μm×10 μm surface area, as determined by atomic force microscope (AFM), for a series of compositionally-graded Si₁₋ₓGeₓ layers, grown at different growth temperatures (800° C., 850° C. and 900° C.), Si₁₋ₓGeₓ graded layer thickness, in μm, and capping layer Si_{0.8}Ge_{0.2} thickness, in μm.

TABLE 1
Surface roughness for Si_{0.8}Ge_{0.2} layers on graded (10% Ge/μm) Si₁₋ₓGeₓ

| | | Thickness | Average Roughness, |
|---|---|---|---|
| Growth | Si₁₋ₓGeₓ Grade | of Capping | nm 10 μm × 10 μm, |
| Temperature, ° C. | Thickness, μm | Si_{0.8}Ge_{0.2}, μm | AFM |
| 900 | 2.0 | 2.0 | 2.5 |
| 850 | 1.5 | 1.5 | 2.0 |
| 800 | 2.0 | 2.0 | 0.9 |

The data in Table 1 show that for Si_{0.8}Ge_{0.2} layers deposited onto a compositionally-graded layer, the surface roughness is a function of the growth temperature, with lower growth temperatures producing smoother films. The smoothest film had an average surface roughness of 0.9 nm at a growth temperature of 800° C.

Unfortunately, films grown at lower temperatures have higher levels of threading dislocation densities than corresponding films grown at higher temperatures. Accordingly, the requirements of concurrently obtaining smooth films for semiconductor device manufacture, and low levels of threading dislocation defects, are opposed to one another in respect of the growth temperature regimes that may be employed.

The approach of the present invention, rather than attempting to synthesize these competing requirements in favor of a single growth temperature that will yield low surface roughness and low levels of threading defects, is to modulate the growth temperature during the growth of the graded Si₁₋ₓGeₓ layer, to achieve a strikingly lower level of threading defects and surface roughness than is possible with isothermal growth processes.

Table 2 illustrates the unexpected improvement that results from modulation of temperature conditions during the growth of the graded Si₁₋ₓGeₓ layer. Data are shown for three different growth temperature regimes, one in which isothermal growth is conducted at a temperature of 800° C., another in which isothermal growth is conducted at a temperature of 900° C., and a third in which temperature ramping was carried out as hereinafter more fully described.

TABLE 2
Surface roughness and threading dislocation density

| Growth | Threading Dislocation | Average Roughness, nm |
|---|---|---|
| Temperature, ° C. | Density, cm² | 10 μm × 10 μm, AFM |
| 800 | 4 × 10⁵ | 0.9 |
| 900 | 4 × 10⁴ | 2.5 |
| Temperature Ramp | 4 × 10⁴ | 0.9 |

Table 2 shows the impact of growth temperature on both threading dislocation density and roughness. Although an isothermal growth of the Si₁₋ₓGeₓ layer at 800° C. produced an average AFM surface roughness of 0.9 nm, the threading defect density was high at 4×10⁵ threading defects/cm². By increasing the temperature of the isothermal growth regime to 900° C., the threading defect density was decreased to 4×10⁴ threading defects/cm², but the average surface roughness increased dramatically, to 2.5 nm. In contrast to these isothermal approaches, the temperature ramping approach of the present invention produced a graded Si₁₋ₓGeₓ material that exhibited a 10-fold reduction in threading defects from the level achieved at 800° C., with a surface roughness that was over 60% lower than the level achieved by isothermal growth at 900° C.

Thus, the ramped temperature growth technique of the present invention produced a graded Si₁₋ₓGeₓ film having a combination of low surface roughness (<1 nm) and low dislocation defect density (<1×10⁵ threading defects/cm², preferably <5×10⁴ threading defects/cm²) that were unachievable by either isothermal technique alone.

The ramped growth process producing the data shown in Table 2 included ramping of temperature as well as ramping of germane (GeH₄) flow rate. The ramped growth process was conducted at a pressure of 20 Torr, a flow rate of 25 standard liters per minute of hydrogen gas (H₂), and a flow rate of 100 standard cubic centimeters per minute (sccm) of dichlorosilane (DCS).

The process included two phases, with the first phase involving ramping of germane flow rate at a constant temperature of 900° C., and with germane flow rate being progressively increased during the successive time periods of the process, as set out in Table 3.

The second phase of the process involved ramping of temperature at a constant flow rate of germane of 60 standard cubic centimeters per minute (sccm), with the temperature being progressively decreased over successive 30 second intervals as set out in Table 4.

In both phases the flow rate of germane is set out for a stream containing 10% by weight GeH₄ in hydrogen carrier gas.

TABLE 3
GeH₄ flow ramping @ 900° C.
(Process Conditions: 20 Torr, 25 slm H₂, 100 sccm DCS)

| GeH₄(10%), sccm | Deposition time, sec |
|---|---|
| 0-18 | 155 |
| 18-31 | 110 |
| 31-44 | 97 |
| 44-60 | 105 |

TABLE 4
Temperature Ramping @ 60 sccm GeH₄ (10%)
(Process Conditions: 20 Torr, 25 slm H₂, 100 sccm DCS)

| Deposition temperature, ° C. | Deposition time, sec |
|---|---|
| 900-883 | 30 |
| 883-872 | 30 |
| 872-861 | 30 |
| 861-850 | 30 |
| 850-842 | 30 |
| 842-834 | 30 |
| 834-826 | 30 |
| 826-817 | 30 |
| 817-809 | 30 |
| 809-803 | 30 |
| 803-796 | 30 |
| 796-790 | 30 |
| 790-784 | 30 |
| 784-778 | 30 |

After forming the graded Si₁₋ₓGeₓ film by the ramped technique described above, the film was capped with a constant-composition layer of Si_{0.8}Ge_{0.2} for analysis.

In the illustrative embodiment of the ramped graded Si₁₋ₓGeₓ film forming process of the invention, the process was begun at 900° C. to avoid significant spontaneous gas-phase nucleation and excessive coating of the gas-phase reactor chamber in which the deposition was carried out, such as were observed when carrying out the process at higher temperatures. It will nonetheless be recognized that specific temperature conditions will vary in the broad practice of the invention, with respect to the specific matrix of process conditions employed, the gas-phase reactor utilized, and the specific precursors that are employed, as can be readily determined without undue experimentation, based on the disclosure hereof.

Further, while vapor deposition techniques are preferred for forming the graded Si₁₋ₓGeₓ film in the practice of the invention, it will be recognized that other film-forming techniques can advantageously be employed, and will require corresponding variation of process conditions based on similar considerations, as is readily determinable within the skill of the art, based on the disclosure herein.

Preferred growth temperature ranges usefully employed in the practice of the ramped temperature process of the present invention will depend on the ultimate composition of the SiGe “virtual substrate” that is produced by the inventive process. In general, however, it is preferred to begin the compositional grading growth process at temperature on the order of approximately 900° C. or higher depending on the specific precursor (source reagent) chemistry that is employed. For an ultimate (grown material top surface) composition of Si_{0.8}Ge_{0.2}, it is preferred that the final stages of the growth process are carried out at temperature on the order of approximately 800° C., e.g., in a range of from about 775° C. to about 825° C.). Similar results can be achieved for higher ultimate Ge-content at final growth temperatures below 800° C.

The temperature ramping process of the invention is to be distinguished from the Molecular Beam Epitaxy (MBE) technique disclosed in Brasen et al. U.S. Pat. No. 5,221,413. In MBE reactors, it is necessary to grow under conditions that maintain a low vapor pressure, since germanium otherwise will tend to evaporate. Brasen fails to describe a suitable method for producing as-grown films with roughness levels below 1 nm. Although Brasen describes growing CVD films at ˜900° C., we have found that surface roughness tends to degrade at this temperature once the peak Ge-content of the film exceeds about 10 atomic percent Ge. The temperature ramping technique of the present invention overcomes such deficiency and permits superior results to be achieved at Ge-content levels above 10 atomic percent.

Similar distinction is applicable to the process described in Bensahel et al. U.S. Pat. No. 6,117,750, which utilizes low temperatures and is unable to achieve the superior surface smoothness that is characteristic of the graded Si₁₋ₓGeₓ films produced by the method of the present invention.

The temperature ramping in the practice of the invention can be carried out in a linear or non-linear manner, as regards the progressive change of the growth temperature. The temperature ramping can be conducted concurrently with ramping of the germanium source, e.g., germane, so that temperature and Ge source material flow rate are each contemporaneously varied in the course of the growth operation. The ramping procedure may be carried out during the entire growth process, or alternatively, ramping may be carried out only during a portion of the growth process, as necessary or desirable in a given application of the invention.

The process of the invention may be employed to form step or step-graded Si₁₋ₓGeₓ films.

Any suitable deposition techniques may be employed to form the low defect density, low surface roughness Si₁₋ₓGeₓ films of the invention, with chemical vapor deposition techniques being most preferred. CVD may be carried out at any suitable conditions within the scope of the disclosure herein, including techniques such as reduced pressure CVD, ultra-high vacuum CVD, atmospheric pressure CVD, plasma-assisted CVD, etc.

Germanium and silicon source materials useful in forming the low defect density, low surface roughness Si₁₋ₓGeₓ films of the invention may be of any suitable type, including germanium sources such as germane (GeH₄), halogermanes whose halo moiety is chlorine, fluorine, iodine or bromine, such as chlorogermanes of the formula GeHₓCl₄₋ₓ wherein x is an integer having a value of from 1 to 3 inclusive, and silicon sources such as silane (SiH₄), Si₃H₈, Si₂H6 and halosilanes whose halo moiety is chlorine, fluorine, iodine or bromine, such as chlorosilanes of the formula SiHₓCl₄₋ₓ wherein x is an integer having a value of from 1 to 3 inclusive.

After the low defect density, low surface roughness Si₁₋ₓGeₓ material of the invention is formed, a capping layer may then be grown. The capping material may be Si₁₋ₓGeₓ grown at the ultimate composition of the underlying top surface Si₁₋ₓGeₓ material, followed by strained silicon or other heterostructural material (e.g., Ge, GaAs, AlAs, AlGaAs, etc., and related ternary and quaternary semiconductors), or strained silicon or other heterostructural material may simply be formed on the low defect density, low surface roughness Si₁₋ₓGeₓ material without an intervening Si₁₋ₓGeₓ capping layer, as necessary or desired in a given application of the present invention.

The Si₁₋ₓGe₁ material of the invention may be formed at any suitable film thickness necessary or desirable in a given application of the invention. In one embodiment, the Si₁₋ₓGeₓ material is formed in a thin film having a material thickness of 0.01 μm to 3,000 μm, although greater or lesser film thicknesses may be employed in the broad practice of the invention, depending on the specific application of the graded silicon-germanium layer.

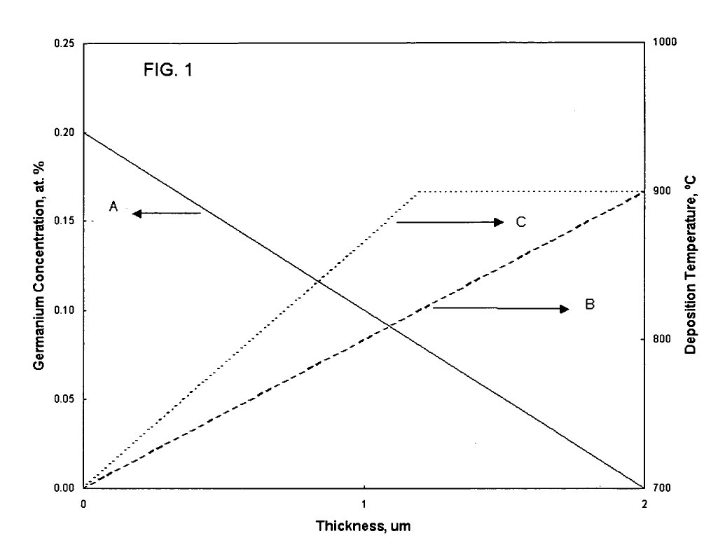

Referring now to the drawings, FIG. 1 is a graph of germanium concentration in atomic percent as a function of thickness in a graded 2 μm thick Si₁₋ₓGeₓ layer (line A), with lines B and C showing deposition temperature, in ° C., as a function of layer thickness during the deposition process.

Curve A in FIG. 1 shows a linear grade in germanium in a Si₁₋ₓGeₓ layer, corresponding to a compositional grading rate of 10% Ge/μm. Curve C describes the temperature ramp conditions used in the illustrative embodiment described hereinabove in connection with Tables 3 and 4 hereof, and Curve B is an alternative temperature ramp for achievement of comparable results. Curve B describes the simplest case of a linear temperature ramp over the entire range of film thickness. In the process corresponding to curve C, an initial portion of the Si₁₋ₓGeₓ layer is grown at constant temperature followed by growth of the remainder of the Si₁₋ₓGeₓ layer under temperature ramping conditions. During the constant temperature portion of the process, the flow rate of the germanium source, GeH₄, is varied to control the linear grading of the germanium concentration in the film. Temperature ramping, as indicated hereinabove, may be linear or non-linear as regards the change of temperature during the relevant portion of the growth process in which the temperature is varied.

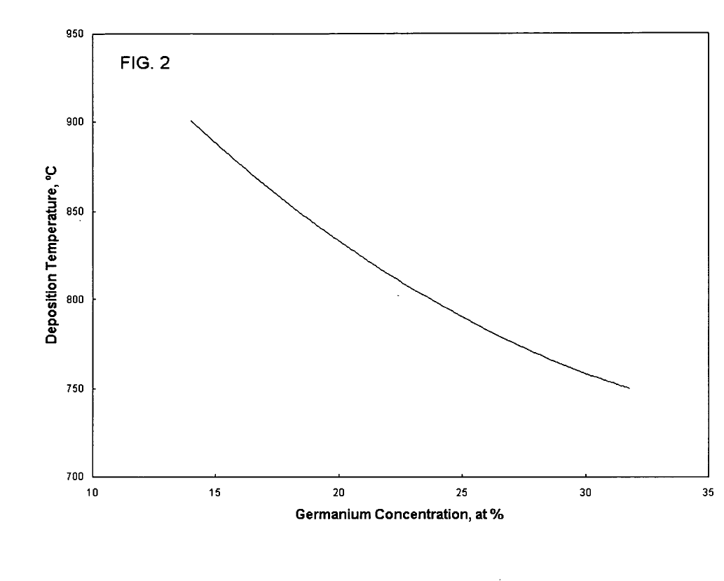

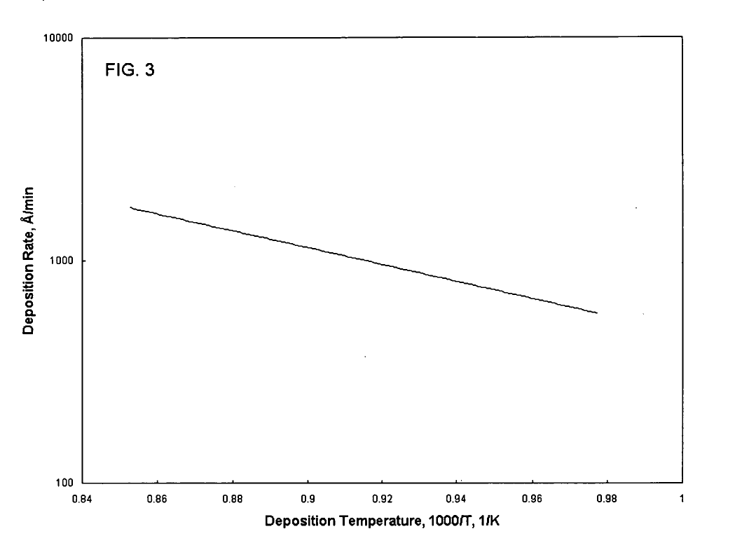

To determine the conditions necessary for the temperature ramping profile shown in FIG. 1, the process data shown in FIGS. 2 and 3 was collected.

FIG. 2 is a graph of deposition temperature, in ° C., as a function of germanium concentration, in atomic percent, of a Si₁₋ₓGeₓ layer formed in accordance with the present invention.

FIG. 3 is an Arrhenius plot of Si₁₋ₓGeₓ deposition rate, in Å/minute, as a function of the inverse deposition temperature, in units of 10³×° K⁻¹, for a Si₁₋ₓGeₓ layer formed in accordance with the present invention.

In generating the graph of FIG. 2, the germanium concentration in an epitaxial layer was recorded for a specific set of process conditions while the deposition temperature was varied. The variable temperature was recorded on the y-axis to facilitate use of the data in establishing the temperature ramp. FIG. 3 is an Arrhenius plot of deposition rate versus temperature from the same set of experiments used to generate FIG. 2. To construct the temperature ramp, the endpoint germanium concentrations in the Si₁₋ₓGe₁ graded film were first specified. For the curve in FIG. 2, the lowest germanium concentration indicated was 15% at 900° C. This was the lower starting concentration for the set of conditions under which these data were collected. Similar to curve C in FIG. 1, the beginning of the temperature ramp in this case was at 15% germanium concentration. Lower initial concentrations are possible by simply adjusting the process conditions and constructing a curve similar to the one in FIG. 2. In the case where the Si₁₋ₓGeₓ layer was to be graded to 25% germanium concentration, the final temperature was determined to be approximately 780° C. Thus, the temperature was determined to be linearly graded from 900° C. to 780° C.

The FIG. 3 Arrhenius plot was used to calculate the deposition time at each temperature interval in the temperature ramp, to obtain the compositional grading in curve A of FIG. 1.

In another illustrative embodiment, linear temperature ramping was carried out over the entire growth of the graded Si₁₋ₓGeₓ layer as set out in Table 5 below, at the process conditions set out in the header of such table for pressure (in Torr), hydrogen gas flow rate (in standard liters per minute), dichlorosilance flow rate (in standard cubic centimeters per minute) and germane flow rate (in standard cubic centimeters per minute, of a 10% by weight germane in hydrogen carrier gas).

TABLE 5
Deposition Time for Temperature Ramping
(Process Conditions: 10 Torr, 30 slm H₂, 100 sccm DCS,
20 sccm GeH₄(10%))

| Deposition Temperature, ° C. | Deposition Time, min |
|---|---|
| 900-840 | 20 |
| 840-800 | 20 |
| 800-770 | 20 |
| 770-745 | 20 |
| 745-735 | 20 |
| 735-720 | 20 |
| 720-700 | 25 |

At the beginning of the deposition process, the temperature was 900° C. and was linearly ramped for 20 minutes to 840° C. The linear temperature ramping was continued in 20-minute segments until a temperature of 700° C. was reached. The temperature ramp alternatively could have been segmented into smaller or larger time intervals, as necessary or desirable to form the graded Si₁₋ₓGeₓ layer in a specific application of the present invention. The film was then capped with a constant-composition layer of Si_{0.8}Ge_{0.2} for analysis.

It is possible to use temperature-ramped growth to increase the average grading rate of the Si₁₋ₓGeₓ film, while still maintaining acceptable defect levels and surface roughness. The advantages of increasing the grading rate include (i) reducing the processing time and cost of the Si₁₋ₓGeₓ film formation process, and (ii) forming thinner Si₁₋ₓGeₓ film layers of improved heat conduction characteristics, since SiGe alloys have lower thermal conductivity than pure silicon, and thinner films therefore improve heat conduction in electronic devices fabricated on such layers.

In another illustrative embodiment of the invention, a Si₁₋ₓGeₓ thin film was formed in which grading began at nominally 10 atomic % Ge per micron of film thickness, but at increased concentration of atomic % Ge, the grading rate was increased to 40 atomic % Ge per micron of film thickness, producing a Si₁₋ₓGeₓ thin film with a defect density of 1.1×10⁵ threading dislocation defects/cm², and a surface roughness of 0.9 nm.

The data for the isothermal ramping of the germane flow rate in the initial portion of such process are set out in Table 6 below, together with the process conditions of pressure (in Torr), flow rate of hydrogen gas (in standard liters per minute), flow rate of dichlorosilane (in standard cubic centimeters per minute), and flow rate of hydrogen chloride (in standard cubic centimeters per minute).

TABLE 6
Initial portion of Si₁₋ₓGeₓ film-forming process - Isothermal
ramping at 10%/micron thickness.
(Process Conditions: 20 Torr, 20/5 slm H₂, 100 sccm DCS, 100 sccm HCl)
Ramp began at 0% Ge and ended at 10% Ge.
GeH₄ Ramp @900° C.

| GeH₄ (10%), | Deposition time, |
|---|---|
| sccm | sec |
| 6 | 10 |
| 18 | 146 |
| 31 | 110 |
| 44 | 97 |
| 60 | 105 |

The data for the temperature ramping in the subsequent portion of the Si₁₋ₓGeₓ film-forming process are set out in Table 7 below, together with the process conditions of pressure (in Torr), flow rate of hydrogen gas (in standard liters per minute), flow rate of dichlorosilane (in standard cubic centimeters per minute), and flow rate of hydrogen chloride (in standard cubic centimeters per minute).

TABLE 7
Subsequent portion of Si₁₋ₓGeₓ film-forming process -
Temperature Ramping at 40% Ge/micron thickness
(Process Conditions: 20 Torr, 20/5 slm H₂, 100 sccm DCS, 100 sccm HCl)
Ramp began at 10% Ge and ended at 20% Ge.
Temperature Ramp @ 60 sccm GeH₄

| | Temp Ramp, | Deposition |
|---|---|---|
| T, ° C. | ° C./sec | time, sec |
| 900-775 | 1 | 125 |

The Si₁₋ₓGeₓ film then was capped with a constant-composition layer of Si_{0.8}Ge_{0.2} for analysis.

The foregoing illustrative embodiments reflect the advantages of the process of the present invention in forming graded Si₁₋ₓGeₓ (0<x<1) films that possess low surface roughness and low threading dislocation density, e.g., <1×10⁵ threading dislocation defects/cm² of surface area. Such low surface roughness, low threading dislocation density compositionally-graded material is usefully employed for fabricating heterostructures such as Si₁₋ₓGeₓ/Si structures.

The process of the invention as illustratively described herein is readily carried out in a simple manner, e.g., using chemical vapor deposition techniques, wherein temperature is selectively modulated during the growth of the graded Si₁₋ₓGeₓ (0<x<1) material, optionally with modulation of the precursor flow rate to the substrate, to produce virtual substrate structures amenable to coating with strained lattice material such as strained silicon. In a particularly preferred embodiment, the process of the invention is conducted to produce compositionally-graded, strain-relaxed Si₁₋ₓGeₓ (x≦0.3) material with surface roughness less than 1 nm, and threading dislocation density <1×10⁵ threading dislocation defects/cm² of surface area.

It will therefore be appreciated that while the invention has been illustratively described herein with reference to particular aspects, features and embodiments, the invention may be practiced with variations and modifications and in other embodiments, as will suggest themselves to those of ordinary skill in the art, based on the disclosure herein. Accordingly, the invention is intended to be broadly interpreted and construed to encompass all such variations, modifications and other embodiments, as being within the spirit and scope of the claims hereinafter set forth.

1. A compositionally-graded, strain-relaxed Si₁₋ₓGeₓ material having a surface roughness of less than 1 nm, wherein 0<x<1.

2. The compositionally-graded, strain-relaxed Si₁₋ₓGeₓ material of claim 1, wherein x≦0.3.

3. The compositionally-graded, strain-relaxed Si₁₋ₓGeₓ material of claim 1, having a threading dislocation density <1×10⁵ threading dislocation defects/cm² of surface area.

4. The compositionally-graded, strain-relaxed Si₁₋ₓGeₓ material of claim 1, having a threading dislocation density <5×10⁴ threading dislocation defects/cm² of surface area.

5. The compositionally-graded, strain-relaxed Si₁₋ₓGeₓ material of claim 1, having a thickness in a range of from about 0.01 μm to about 3,000 μm.

6. The compositionally-graded, strain-relaxed Si₁₋ₓGeₓ material of claim 1, wherein said surface roughness is ≦0.9 nm.

7. A compositionally-graded, strain-relaxed Si₁₋ₓGeₓ (x≦0.3) material with surface roughness less than 1 nm, and threading dislocation density <1×10⁵ threading dislocation defects/cm² of surface area.

8. The compositionally-graded, strain-relaxed Si₁₋ₓGeₓ material of claim 7, having a threading dislocation density <5×10⁴ threading dislocation defects/cm² of surface area.

9. The compositionally-graded, strain-relaxed Si₁₋ₓGeₓ material of claim 7, having a thickness in a range of from about 0.01 μm to about 3,000 μm.

10. The compositionally-graded, strain-relaxed Si₁₋ₓGeₓ material of claim 10, wherein said surface roughness is ≦0.9 nm.

11. An epitaxial heterostructure, comprising a compositionally-graded, strain-relaxed Si₁₋ₓGeₓ epitaxial layer having a surface roughness of less than 1 nm, wherein 0<x<1, and a heterostructural material deposited on the compositionally-graded, strain-relaxed Si₁₋ₓGeₓ epitaxial layer.

12. The epitaxial heterostructure of claim 11, wherein the heterostructural material comprises strained silicon.

13. The epitaxial heterostructure of claim 11, wherein the heterostructural material comprises a material selected from the group consisting of Si, Ge, GaAs, AlAs, AlGaAs, and related ternary and quaternary semiconductors.

14. The epitaxial heterostructure of claim 11, wherein x≦0.3.

15. The epitaxial heterostructure of claim 11, wherein the compositionally-graded, strain-relaxed Si₁₋ₓGeₓ epitaxial layer has a threading dislocation density <1×10⁵ threading dislocation defects/cm² of surface area.

16. The epitaxial heterostructure of claim 11, wherein the compositionally-graded, strain-relaxed Si₁₋ₓGeₓ epitaxial layer has a threading dislocation density <5×10⁴ threading dislocation defects/cm² of surface area.

17. The epitaxial heterostructure of claim 11, wherein the compositionally-graded, strain-relaxed Si₁₋ₓGeₓ epitaxial layer has a surface roughness less than 0.9 nm.

18. The epitaxial heterostructure of claim 11, further comprising a silicon on insulator (SOI) wafer.

19. The epitaxial heterostructure of claim 11, wherein the heterostructural material includes a cap layer of strained Si, overlying the compositionally-graded, strain-relaxed Si₁₋ₓGeₓ epitaxial layer, and a further cap layer of SiGe, overlying the cap layer of strained Si.

20. A compositionally-graded, strain-relaxed Si₁₋ₓGeₓ epitaxial layer on a substrate formed by a process comprising contacting silicon and germanium precursor gases with the substrate under vapor deposition conditions comprising controlled temperature ramping, wherein the compositionally-graded, strain-relaxed Si₁₋ₓGeₓ epitaxial layer has a surface roughness of less than 1 nm and a threading dislocation density less than 1×10⁵ threading dislocation defects/cm² of surface area.

21. A method of forming on a substrate a compositionally-graded, strain-relaxed Si₁₋ₓGeₓ (0<x<1) epitaxial layer having a surface roughness of less than 1 nm, the method including contacting silicon and germanium precursors with the substrate under Si₁₋ₓGeₓ (0<x<1) epitaxial layer growth conditions, and varying temperature during at least part of said contacting.

22. The method of claim 21, wherein said step of varying temperature comprises temperature ramping.

23. The method of claim 22, wherein said temperature ramping is linear.

24. The method of claim 22, wherein said temperature ramping is non-linear.

25. The method of claim 22, wherein said temperature ramping is conducted in a temperature range of from about 900° C. to about 700° C.

26. The method of claim 22, wherein said temperature ramping is conducted in a temperature range of from about 900° C. to about 800° C.

27. The method of claim 21, wherein said step of varying temperature during at least part of said contacting, is conducted to yield the compositionally-graded, strain-relaxed Si₁₋ₓGeₓ (0<x<1) epitaxial layer, having a threading dislocation density less than 1×10⁵ threading dislocation defects/cm² of surface area.

28. The method of claim 21, wherein said step of varying temperature is conducted during part of said contacting, and said contacting further includes constant temperature Si₁₋ₓGeₓ (0<x<1) epitaxial layer growth conditions during another part thereof.

29. The method of claim 28, wherein said constant temperature is in a range of from about 775° C. to about 825° C.

30. The method of claim 21, wherein the compositionally-graded, strain relaxed Si₁₋ₓGeₓ epitaxial layer comprises step or step graded Si₁₋ₓGeₓ structure.

31. The method of claim 21, wherein x≦0.3.

32. The method of claim 31, wherein the compositionally-graded, strain-relaxed Si₁₋ₓGeₓ (0<x<1) epitaxial layer, having a threading dislocation density less than 1×10⁵ threading dislocation defects/cm² of surface area.

33. The method of claim 21, wherein said contacting step comprises chemical vapor deposition.

34. The method of claim 21, wherein said contacting step comprises reduced pressure chemical vapor deposition.

35. The method of claim 21, wherein said contacting step comprises ultra-high vacuum chemical vapor deposition.

36. The method of claim 21, wherein said contacting step comprises atmospheric pressure chemical vapor deposition.

37. The method of claim 21, wherein said contacting step comprises plasma-assisted chemical vapor deposition.

38. The method of claim 21, wherein said germanium precursor comprises a precursor species selected from the group consisting of germane (GeH₄) and halogermanes.

39. The method of claim 38, wherein said germanium precursor comprises a precursor species selected from the group consisting of chlorogermanes of the formula GeHₓCl₄₋ₓ wherein x is an integer having a value of from 1 to 3 inclusive.

40. The method of claim 21, wherein said silicon precursor comprises a precursor species selected from the group consisting of silane (SiH₄), Si₃H₈, Si₂H₆ and halosilanes.

41. The method of claim 40, wherein said silicon precursor comprises a precursor species selected from the group consisting of chlorosilanes of the formula SiHₓCl₄₋ₓ wherein x is an integer having a value of from 1 to 3 inclusive.

42. The method of claim 22, further comprising ramping said germanium precursor during at least a portion of said contacting step.

43. The method of claim 42, wherein said germanium precursor ramping is conducted concurrently with said temperature ramping during at least a portion of said temperature ramping.
